(19) United States
(12) Patent Application Publication
(10) Pub. No.: US 2023/0386829 A1
(43) Pub. Date: Nov. 30, 2023

(54) LOW TEMPERATURE SILICON OXIDE GAP FILL

(71) Applicant: Applied Material, Inc., Santa Clara, CA (US)

(72) Inventors: Soham Asrani, San Jose, CA (US); Bhargav S. Citla, Fremont, CA (US); Srinivas D. Nemani, Saratoga, CA (US); Ellie Y. Yieh, San Jose, CA (US)

(73) Assignee: Applied Materials, Inc., Santa Clara, CA (US)

(21) Appl. No.: 17/827,652

(22) Filed: May 27, 2022

(51) Int. Cl. H01L 21/02; H01L 21/3065

(52) U.S. Cl. CPC H01L 21/02238; H01L 21/02532; H01L 21/0262; H01L 21/3065; H01L 21/02164; H01L 21/0243; H01L 21/02381

(57) ABSTRACT

Embodiments of the disclosure relate to methods for forming silicon based gapfill within substrate features. A flowable silicon film is formed within the feature with a greater thickness on the bottom and top surfaces than the sidewall surface. An etch plasma removes the silicon film from the sidewall surface. A conversion plasma is used to convert the silicon film to a silicon based gapfill (e.g., silicon oxide). In some embodiments, the silicon film is preferentially converted on the top and bottom surface before being etched from the sidewall surface.

### TECHNICAL FIELD

Embodiments of the disclosure generally relate to methods of providing silicon based gap fill in high aspect ratio structures. In particular, some embodiments of the disclosure pertain to methods of forming silicon oxide gap fill at low temperatures without steam.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations.

In gap filling operations, a material may be formed or deposited to fill a trench or other feature formed on a semiconductor substrate. As features may be characterized by higher aspect ratios and reduced critical dimensions, certain filling methods may be inadequate. For example, some methods deposit more material at the top and along sidewalls of the narrower features. Continued deposition by these methods may pinch off the feature, including between sidewalls within the feature, and may produce voids therein. These voids adversely impact device performance and subsequent processing operations.

In specific, current methods for depositing silicon oxide rely on steam based processes which utilize relatively high temperatures. However, the underlying structures to be filled often comprise exposed silicon or silicon-germanium materials which may be oxidized by these high temperature steam conditions. Some methods for depositing silicon oxide gap fill use multiple chambers to meet the material requirements of the gap fill material. These multi-chamber process have longer processing times and poor throughput.

Therefore, there is a need in the art for new methods of depositing gap fill materials in high aspect ratio and/or low critical dimension features. Specifically, there is also a need for silicon oxide gap fill without steam, at relatively low temperatures and which can be performed in-situ within a single processing chamber.

### SUMMARY

One or more embodiments of the disclosure are directed to a method of depositing silicon based gapfill. The method comprises depositing a flowable silicon film on a substrate surface having at least one feature therein. The feature has an opening width, one or more sidewall, and extends a depth from a top surface of the substrate to a bottom. The flowable silicon film is deposited as a top material on the top surface, as a sidewall material on the one or more sidewall, and as a bottom material on the bottom. The sidewall material is selectively etched over the top material and the bottom material. The top material and the bottom material are converted to form a converted material.

Additional embodiments of the disclosure are directed to a method of depositing silicon based gapfill. The method comprises depositing a flowable silicon film on a substrate surface having at least one feature therein. The feature has an opening width, one or more sidewall, and extends a depth from a top surface of the substrate to a bottom, the flowable silicon film being deposited as a top material on the top surface, as a sidewall material on the one or more sidewall, and as a bottom material on the bottom. The top material and the bottom material are selectively converted to form a converted material. The sidewall material is selectively etched over the converted material.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a schematic cross-sectional view of an exemplary processing chamber according to one or more embodiments;

FIG. 2 illustrates a process flow diagram of a processing method according to one or more embodiments; and

FIGS. 3A-3C illustrate a cross-sectional view of a substrate during processing according to one or more embodiments.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter or appended number that distinguishes among the similar components. If only the first reference label is used in the specification, the description is applicable to any one of the similar components having the same first reference label irrespective of the letter or appended number.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to an operation to or on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the disclosure provide methods for depositing silicon based gapfill. Some embodiments of the disclosure provide gap fill at relatively low temperatures. Some embodiments provide gap fill in a bottom-up fashion. Some embodiments provide gap fill without seams or voids. Some embodiments provide gap fill in situ, within a single processing chamber. Further embodiments advantageously provide methods of depositing silicon oxide gap fill. Some embodiments provide silicon oxide gap fill without the use of steam.

Amorphous silicon may be used in semiconductor device manufacturing for a number of structures and processes, including as a sacrificial material, for example as a dummy gate material, or as a trench fill material. In gap filling operations, some processing may utilize flowable films formed under process conditions to limit conformality of deposition, which may allow the deposited material to better fill features on the substrate. Flowable silicon material may be characterized by relatively high amounts of hydrogen and may be less dense than other formed films. Consequently, subsequent treatment operations may be performed to cure the produced films. Conventional technology may utilize a UV curing process to remove hydrogen and process the film. However, UV curing may result in significant film shrinkage, which may cause stress on features as well as produce voids within the structure.

As feature sizes continue to shrink, flowable films may be challenged for narrow features, which may be further characterized by higher aspect ratios. For example, pinching of the feature may more readily occur due to deposition on sidewalls of the feature, which in small feature sizes may further restrict flow further into the feature, and may produce voids. The present technology may overcome these limitations by performing a directional treatment of material formed in the feature that may not be performed on material deposited on the sidewalls. Additionally, the present technology may perform a selective etch and/or modification of the formed film during a curing operation that is capable of removing the material on the sidewalls, while maintaining the material near the bottom of the feature. This may limit or prevent sidewall coverage during trench fill, allowing improved fill operations to be performed.

After describing general aspects of a chamber according to some embodiments of the present technology in which plasma processing operations discussed below may be performed, specific methodology will be discussed. It is to be understood that the present technology is not intended to be limited to the specific films, chambers, or processing discussed, as the techniques described may be used to improve any number of film formation processes and may be applicable to a variety of processing chambers, operations, and materials.

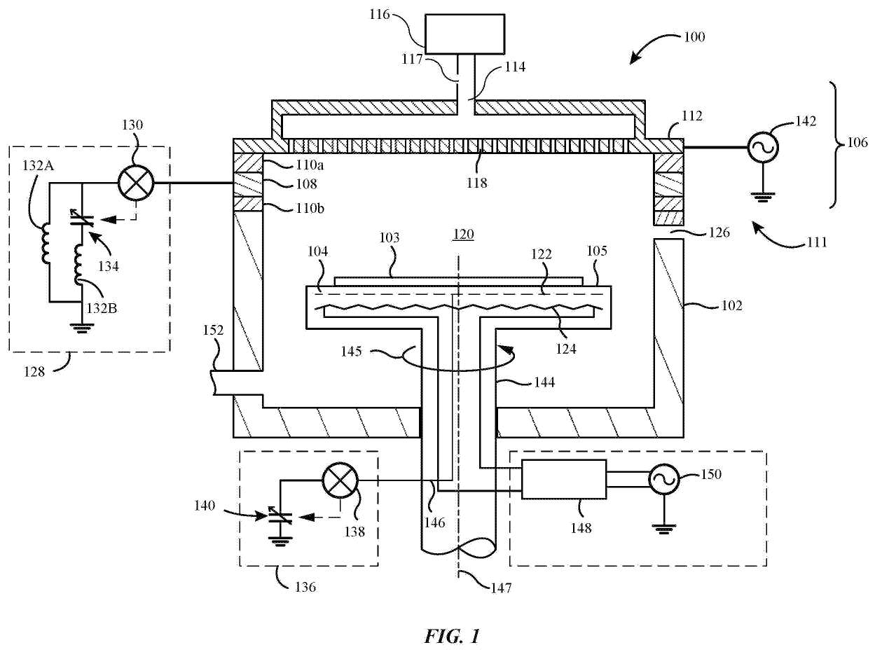

FIG. 1 shows a cross-sectional view of an exemplary processing chamber 100 according to some embodiments of the present technology. The figure illustrates an overview of a system incorporating one or more aspects of the present technology, and/or which may perform one or more deposition or other processing operations according to embodiments of the present technology.

Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Similarly, the substrate support 104 may be raised or lowered as necessary for loading and unloading of the substrate 103.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102 and may separate the chamber body 102 from other components of the lid assembly 106. The first electrode 108 may be part of the lid assembly 106 or may be a separate sidewall electrode. The first electrode 108 may be an annular or ring-like member and may be a ring electrode. The first electrode 108 may be a continuous loop around a circumference of the processing chamber 100 surrounding the processing volume 120 or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, comprising a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber 100. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Inlet 114 may include delivery from a remote plasma source unit 116, which may be fluidly coupled with the chamber, as well as a bypass 117 for process gas delivery that may not flow through the remote plasma source unit 116. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 1328, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

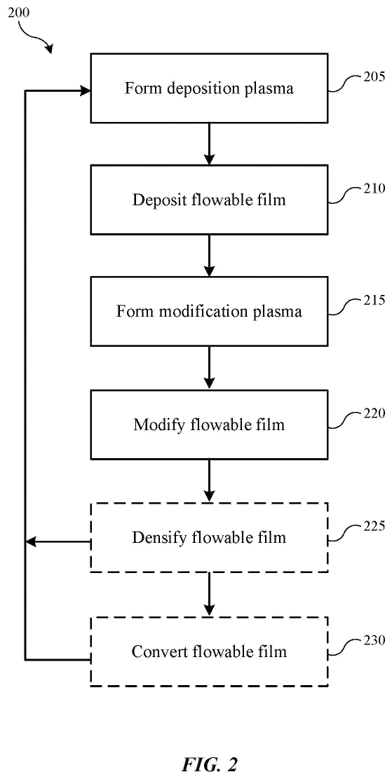

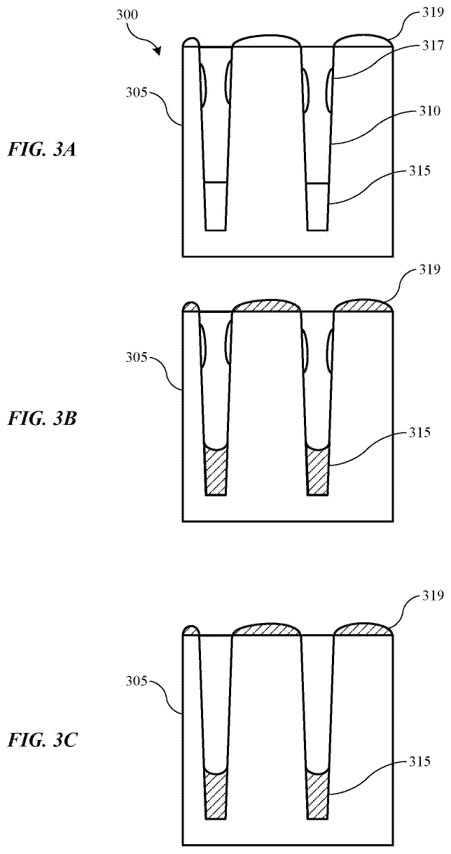

Processing chamber 100 may be utilized in some embodiments of the present technology for processing methods that may include formation, treatment, etching, or conversion of materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Further, it should be noted that, as discussed below the order of the operations identified in FIG. 2 may be modified. For example, in some embodiments, a film may be converted before being modified or densified. Additionally, as also discussed below, it may not be necessary to perform each operation during each process cycle. For example, in some embodiments, a cycle of deposition and modification may be repeated several times before moving on to conversion and then returning to deposition and modification.

Referring to FIG. 2, method 200 may include additional operations prior to initiation of the listed operations. For example, additional processing operations may include forming structures on a semiconductor substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

A substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material in which one or more features 310 may be formed. Substrate 305 may be any number of materials used in semiconductor processing. The substrate material may be or include silicon, germanium, dielectric materials including silicon oxide or silicon nitride, metal materials, or any number of combinations of these materials. Features 310 may be characterized by any shape or configuration according to the present technology. In some embodiments, the features may be or include a trench structure or aperture formed within the substrate 305.

Although the features 310 may be characterized by any shapes or sizes, in some embodiments the features 310 may be characterized by higher aspect ratios, or a ratio of a depth of the feature to a width across the feature. For example, in some embodiments features 310 may be characterized by aspect ratios greater than or about 5:1, greater than or about 10:1, greater than or about 15:1, greater than or about 20:1, greater than or about 25:1, greater than or about 30:1, greater than or about 40:1, or greater than or about 50:1. Additionally, the features may be characterized by narrow widths or diameters across the feature including between two sidewalls, such as a dimension less than or about 20 nm, less than or about 15 nm, less than or about 12 nm, less than or about 10 nm, less than or about 9 nm, less than or about 8 nm, less than or about 7 nm, less than or about 6 nm, or less than or about 5 nm.

In some embodiments, method 200 may include optional treatment operations, such as a pretreatment, that may be performed to prepare a surface of substrate 305 for deposition. Once prepared, method 200 may include delivering one or more precursors to a processing region of the semiconductor processing chamber housing the structure 300. The precursors may include one or more silicon-containing precursors, as well as one or more diluents or carrier gases such as an inert gas or other gas delivered with the silicon-containing precursor. A plasma may be formed of the deposition precursors including the silicon-containing precursor at operation 205. The plasma may be formed within the processing region, which may allow deposition materials to deposit on the substrate. For example, in some embodiments a capacitively-coupled plasma may be formed within the processing region by applying plasma power to the faceplate as previously described.

A silicon-containing material may be deposited on the substrate at operation 210 from plasma effluents of the silicon-containing precursor. The material may be a flowable silicon-containing material in some embodiments, which may be or may include amorphous silicon. The deposited materials may at least partially flow into the features on the substrate to provide a bottom-up type of gap fill. As illustrated in FIG. 3A, material 315 may be deposited on the substrate 305 and may flow into trenches or features 310. As illustrated, the deposited material 315 may flow into the bottom of the feature, although an amount of material may remain on the sidewalls of the substrate as illustrated with material 317, as well as material on top of, or between, features, as illustrated with material 319. Although the amount deposited may be relatively small, the remaining material on the sidewalls may limit subsequent flow. Additionally, if a conventional conversion were performed of the deposited material, such as a conversion to silicon nitride for example, the conversion would involve an expansion of the film. For reduced dimension features, the residual material formed on the sidewalls may be converted and expand outward towards an opposite sidewall. This may cause the feature to be pinched off, which may form voids within the feature.

The power applied during deposition may be a lower power plasma, which may limit dissociation, and which may maintain an amount of hydrogen incorporation in the deposited materials. This incorporated hydrogen may contribute to the flowability of the materials deposited. Additionally, unlike conventional technologies, the present technology may incorporate a bias process, which may produce a treatment to the deposited film during the deposition operations. The process may include utilizing a source power, such as coupled with the faceplate or showerhead as previously described, as well as utilizing a bias power, such as applied through the substrate support as discussed above. The source power may be used to perform a controlled dissociation of the silicon-containing precursor, which may limit dissociation and allow longer material chains to be formed. When these materials contact the substrate, the longer chain silicon-containing materials may have increased flowability, which may improve bottom-up fill.

The source power may be pulsed, and the duty cycle may be reduced, which may further reduce the effective plasma power in some embodiments. For example, the source power may be applied at any higher frequency, such as greater than or about 10 MHz, greater than or about 13 MHz, greater than or about 15 MHz, or greater than or about 20 MHz. The plasma power source may deliver a plasma power to the faceplate of less than or about 300 W, less than or about 250 W, less than or about 200 W, less than or about 150 W, less than or about 100 W, or less than or about 50 W. Additionally, the source power may be pulsed at a pulsing frequency of 20 kHz or less, such as less than or about 15 kHz, less than or about 12 kHz, less than or about 10 kHz, or less than or about 8 kHz. Additionally, the pulsing duty cycle may be applied at less than or about 50%, less than or about 40%, less than or about 30%, less than or about 20%, less than or about 10%, less than or about 5%, or less than or about 1%. This may limit the silicon precursor dissociation and improve long-chain formation as described above.

In some embodiments, to facilitate dissociation and deposition, the deposition precursors may include one or more inert gases, such as argon and/or helium, which may help improve dissociation. Additionally, in some embodiments the deposition precursors may include diatomic hydrogen, which may be flowed to facilitate a treatment process during the deposition, and which may be aided by the bias power provision. For example, hydrogen may be delivered with the silicon-containing precursor at a flow rate ratio of the hydrogen to the silicon-containing precursor of greater than or about 0.5:1, greater than or about 1:1, greater than or about 1.5:1, greater than or about 2:1, greater than or about 2.5:1, greater than or about 3.0:1, greater than or about 3.5:1, or greater than or about 4.0:1.

The hydrogen may also be dissociated in the generated plasma and may be further activated by utilizing a bias power delivery. For example, in some embodiments, a bias power source may be operated at a lower frequency than the source power and may be operated at less than or about 10 MHz, less than or about 5 MHz, or less than or about 2 MHz. The power supply may be operated at a power of less than or about 2000 W, less than or about 1000 W, less than or about 500 W, less than or about 450 W, less than or about 400 W, or less than or about 350 W. The bias power may create an amount of directionality of effluent movement and may allow lighter hydrogen radicals to further dissociate argon and/or helium, which may be directed more specifically downward at the structure. The lower frequency power may also impart additional energy to the ions as they travel in more straight-line paths down to the substrate.

These hydrogen and inert gas radical species may transfer energy to materials along surfaces normal to the direction of travel, such as material along the bottom of features and along the top of features, such as material 315 and 319. The energy may help release excess hydrogen, which may densify the film in these locations. As illustrated in FIG. 3B, while the material 317 along the sidewalls may not be impacted, or may have limited changes, the material 315 and 319 may be densified, which may improve the quality of the materials. Consequently, in some embodiments, material along the top and bottom of the structure may be characterized by a higher quality, which may include an increased density, over material that may have deposited along sidewalls of the features.

However, by utilizing a bias power, the deposition plasma may be characterized by an increased power, which may further dissociate the silicon-containing precursor and reduce flowability. Accordingly, to limit this effect, the bias power may also be pulsed at a pulsing frequency of less than or about 20 kHz, less than or about 10 kHz, less than or about 5 kHz, less than or about 1 kHz, less than or about 500 Hz, less than or about 100 Hz, less than or about 50 Hz, or less than or about 10 Hz. Additionally, the duty cycle may be operated at less than or about 50%, less than or about 40%, less than or about 30%, less than or about 20%, less than or about 10%, less than or about 5%, or about 1%, which may further reduce the impact of the bias power. By operating the bias power at a relatively low pulsing frequency and duty cycle, the bias power may be utilized to increase film quality at the top of the structure and at the bottom of the feature, while limiting an impact on any other deposition characteristics. Additionally, by utilizing a relatively low power, the hydrogen may not be energized sufficiently to cause etching of the deposited material, or lead to sputtering of the material based on bombardment of the inert gas effluents.

Subsequent an amount of deposition, in some embodiments of the present technology an etching and/or modifying process may be performed that is configured to selectively etch back material from the sidewalls of the feature while simultaneously modifying the material at the top and bottom of the feature. This process may be performed in the same chamber as the deposition and may be performed in a cyclic process to fill the feature. In some embodiments the silicon-containing precursor flow may be halted, and the processing region may be purged. The flow of inert gases, such as argon and/or helium, may also be halted. After purging the processing region, a hydrogen-containing precursor or NF₃ may be flowed into the processing region of the processing chamber. In some embodiments, the modification process may only include a hydrogen-containing precursor, which may be diatomic hydrogen in some embodiments. In some embodiments, the modification plasma comprises NF₃. A modification plasma may be formed at operation 215, which may also be a capacitively-coupled plasma formed within the processing region, although in some embodiments an inductively-coupled plasma may similarly be applied.

Similar to the deposition process, during the etching/modification operation, an additional power source may be engaged and coupled with the substrate support as previously described to provide a bias to the plasma generated above the substrate. Accordingly, the etch process may also include both source power and bias power. This may draw plasma effluents to the substrate, which may bombard the film and cause densification of the deposited materials, especially the materials that have already been at least partially improved by the treatment performed during deposition. Although any hydrogen-containing material may be used, in some embodiments diatomic hydrogen may be used as the hydrogen-containing precursor to produce the etching plasma. The hydrogen radicals and ions may readily penetrate the materials formed within the trench and may release incorporated hydrogen from the film causing densification. The bias power applied may be relatively low to limit sputtering of the produced film as well as to limit any potential damage to the structure. Additionally, by adjusting the source power and the bias power applied, an etching operation may be performed, which may reduce sidewall coverage of the deposited material while limiting any effect on the previously treated materials.

Diatomic hydrogen, or any other hydrogen-containing material, may be utilized to generate a plasma within the processing region by delivering power to the faceplate from the plasma power source. Similarly, NF₃ based plasmas may also be used. The plasma power in some embodiments may be greater than a plasma power used during the deposition, both from the source power and the bias power. For example, the plasma source power delivered may be greater than or about 100 W, and may be greater than or about 200 W, greater than or about 300 W, greater than or about 400 W, or greater than or about 500 W. By increasing the plasma power during the modification plasma formation, a greater amount of plasma effluents may be generated. However, as plasma power increases, the amount of material etched from the bottom of the structure may also increase. Accordingly, in some embodiments the plasma source power may be maintained at less than or about 500 W, less than or about 400 W, or less than or about 300 W. Additionally, aspects of the bias power may also be adjusted. For example, in some etch/modification operations the bias power may be higher than the plasma source power, which may provide enough power to the plasma to ensure etching of lower quality materials occurs, such as materials along the sidewalls that may not have been treated during the deposition operation.

Applying greater bias power may increase an ability to etch deposited materials. While the bias power during deposition may be reduced to limit any etching effect, during the etch/modification operation a bias power, which may be at any of the frequencies noted above, may be increased to greater than or about 500 W, greater than or about 800 W, greater than or about 1000 W, greater than or about 1200 W, greater than or about 1400 W, greater than or about 1600 W, or greater than or about 1800 W. However, because the bias power may impart directionality, the bias power may be pulsed as discussed below, which may provide etching of the lower quality material, while maintaining the material previously treated, and which may modify and/or densify the material. The plasma effluents may then etch the flowable film at operation 220 and may remove the flowable film from the sidewalls of the trench.

Simultaneously, and beneficially, plasma effluents delivered more directionally may penetrate the remaining film formed at the bottom of the feature and may reduce hydrogen incorporation to densify the film at optional operation 225. As illustrated in FIG. 3C, material 317 may be removed from sidewalls and overhang regions of the substrate 305, which may maintain the deposited material at bottom regions of the feature and along the top region of the structure. As an added benefit, the densified material 319 at the top of the structure may also protect the underlying material from damage by limiting any impact on the substrate materials 305. The process may also provide a reduced hydrogen incorporation in the remaining material, such as a hydrogen incorporation of less than or about 40 at. %, less than or about 35 at. %, less than or about 30 at. %, less than or about 25 at. %, less than or about 20 at. %, less than or about 15 at. %, less than or about 10 at. %, or less than or about 5 at. %.

Additional adjustments may be made to further increase etching of deposited material along sidewalls of the features by adjusting one or more characteristics of the plasma power or bias power being supplied. For example, in some embodiments both the plasma power source and bias power source may be operated in a continuous wave mode. Additionally, one or both of the power sources may be operated in a pulsed mode. In some embodiments, the source power may be operated in a continuous wave mode while the bias power is operated in a pulsed mode. A pulsing frequency for the bias power may be any of the pulsing frequencies discussed previously. The duty cycle of the bias power may be less than or about 75%, and the bias power may be operated at a duty cycle of less than or about 70%, less than or about 60%, less than or about 50%, less than or about 40%, less than or about 30%, less than or about 20%, less than or about 10%, less than or about 5%, or less. By operating the bias power for a reduced duty cycle, such as an on-time duty of less than or about 50%, a greater amount of time per cycle may be performing a more isotropic etch within the feature, such as during the off time, which may better remove material from the sidewalls.

Additional power configurations may also include an amount of synchronization of the source power and the bias power in a master/slave relationship. For example, both power supplies may be operated in a pulsing orientation, and the bias power may be synchronized to engage after the source power has been engaged at each pulse. A level-to-level pulsing scheme may also be applied. For example, during the on duty of the bias power, the source power may be operated at a first plasma power. During the remainder of the cycle where the bias power is off, the source power may be operated at a second plasma power, which may be greater than the first plasma power. This may both increase isotropic etching by removing the bias-induced directionality and may also increase etching characteristics of the isotropic etch. The deposition and etch processes may be repeated any number of times in cycles to fill the feature.

Additionally, in some embodiments where the silicon may be sought to be converted within the feature, the cycling may also include a conversion operation. By converting during each cycle, penetration issues through the feature may be fully resolved. Also, by performing a conversion operation subsequent to the curing and etching/modification, deposited material may be removed from the sidewalls prior to conversion, which may limit film expansion laterally within the trench or feature between sidewalls as previously described. The conversion may be performed in a different chamber from the deposition and treatment, although in some embodiments two or more, including all operations, may be performed within a single processing chamber. This may reduce queue times over conventional processes.

Method 200 continues with the conversion of the amorphous silicon to another material. For example, subsequent to the etching and densifying, one or more conversion precursors may be delivered to the processing region of the chamber. For example, a nitrogen-containing precursor, an oxygen-containing precursor, and/or a carbon-containing precursor may be delivered to the processing region of the chamber, along with any carrier or diluent gases. A plasma may be formed of the conversion precursor, which may then contact the amorphous silicon material within the feature. At optional operation 230, plasma effluents of the conversion precursor may interact with the amorphous silicon material within the trench, and convert the material to silicon nitride, silicon oxide, silicon carbide, silicon oxynitride, silicon oxycarbide, silicon carbon nitride, or silicon oxycarbonitride, along with any other materials that may be used to convert amorphous silicon films. The plasma power may be similar to powers previously stated, and may be from about 100 W up to about 1,000 W or more for a capacitively-coupled system, as well as up to 10 kW or more for an inductively-coupled plasma system, for example, although any type of conversion may also be performed.

Although the deposition may be formed to several nanometers or more, by performing an etch process as previously described, the thickness of densified material may be controlled to be at a thickness of less than or about 500 A, and may be less than or about 450 A, less than or about 400 A, less than or about 350 A, less than or about 300 A, less than or about 250 A, less than or about 200 A, less than or about 150 A, less than or about 100 A, less than or about 50 A, or less. By controlling the thickness of the deposited material, conversion through the entire thickness may be performed more readily, and penetration issues common in conventional processes may be resolved. After a conversion of deposited material, the process may then be fully repeated to continue to produce the converted material up through the feature.

Any number of precursors may be used with the present technology with regard to the deposition precursors used during any of the formation operations. Silicon-containing precursors that may be used during any silicon formation, silicon oxide formation, or silicon nitride formation may include, but are not limited to, silane (SiH₄), disilane (Si₂H₆), trisilane, tetrasilane, or other organosilanes including cyclohexasilanes, silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing film formation. By utilizing higher order silanes, longer material chains may be produced, which may increase flowability in some embodiments. The silicon-containing material may be nitrogen-free, oxygen-free, and/or carbon-free in some embodiments. Oxygen-containing precursors used in any operation as described throughout the present technology may include O₂, N₂O, NO₂, O₃, H₂O, H₂O₂, as well as any other oxygen-containing precursors that may be used in silicon oxide film formation, or other film formation. Nitrogen-containing precursors used in any operation may include N₂, N₂O, NO₂, NH₃, N₂H₂, as well as any other nitrogen-containing precursor that may be used in silicon nitride film formation. Carbon-containing precursors may be or include any carbon-containing material, such as any hydrocarbon, or any other precursor including carbon. In any of the operations one or more additional precursors may be included, such as inert precursors, which may include Ar, He, Xe, Kr, or other materials such as nitrogen, ammonia, hydrogen, or other precursors.

Temperature and pressure may also impact operations of the present technology. For example, in some embodiments to facilitate film flow, the process may be performed at a temperature below or about 20° C., less than or about 0° C., less than or about −20° C., less than or about −50° C., less than or about −75° C., less than or about −100° C., or lower. The temperature may be maintained in any of these ranges throughout the method, including during the treatment and etching, as well as the conversion. Pressure within the chamber may be kept relatively low for any of the processes as well, such as at a chamber pressure of less than or about 20 Torr, and pressure may be maintained at less than or about 15 Torr, less than or about 10 Torr, less than or about 5 Torr, less than or about 3 Torr, less than or about 2 Torr, less than or about 1 Torr, less than or about 0.1 Torr, or less. By performing processes according to some embodiments of the present technology, improved fill of narrow features utilizing silicon-containing materials may be produced.

As identified above, the etch process to remove material from the feature sidewalls may be performed before or after converting the material. In some embodiments, after deposition, the material is converted as described above. The process conditions are maintained such that the conversion process acts more readily on the bottom material 315 and the top material 319. In contrast, the sidewall material 317 is less affected by the conversion process.

After converting the bottom material 315 and the top material 319, a similar etch process as described above may be applied to remove the sidewall material 317 while leaving the converted bottom material and converted top material substantially unaffected.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

1. A method of depositing silicon based gapfill, the method comprising:
depositing a silicon film on a surface of a substrate having at least one feature therein, the feature having an opening width, one or more sidewall, and extending a depth from a top surface of the substrate to a bottom, the silicon film being deposited as a top material on the top surface, as a sidewall material on the one or more sidewall, and as a bottom material on the bottom;
selectively etching the sidewall material over the top material and the bottom material; and
converting the top material and the bottom material to form a converted material.

2. (canceled)

3. (canceled)

4. The method of claim 1, wherein depositing the silicon film comprises exposing the surface of the substrate to a deposition plasma comprising a plasma of a silicon-containing precursor.

5. The method of claim 4, wherein the silicon-containing precursor comprises one or more of silane, disilane, trisilane or tetrasilane.

6. The method of claim 4, wherein the deposition plasma further comprises one or more of H₂, Ar or He.

7. The method of claim 1, wherein selectively etching the sidewall material comprises exposing the substrate to a directional plasma comprising H₂ or NF₃.

8. The method of claim 1, wherein forming the converted material comprises exposing the surface of the substrate to an oxidant plasma and the converted material comprises silicon oxide.

9. The method of claim 8, wherein the oxidant plasma comprises a cycle of (i) an O₂/Ar plasma or a N₂O/Ar plasma and (ii) an Ar/He plasma.

10. (canceled)

11. A method of depositing silicon based gapfill, the method comprising:
depositing a silicon film on a surface of a substrate having at least one feature therein, the feature having an opening width, one or more sidewall, and extending a depth from a top surface of the substrate to a bottom, the silicon film being deposited as a top material on the top surface, as a sidewall material on the one or more sidewall, and as a bottom material on the bottom;
selectively converting the top material and the bottom material to form a converted material; and
selectively etching the sidewall material over the converted material.

12. (canceled)

13. (canceled)

14. The method of claim 11, wherein depositing the silicon film comprises exposing the surface of the substrate to a deposition plasma comprising a plasma of a silicon-containing precursor.

15. The method of claim 14, wherein the silicon-containing precursor comprises one or more of silane, disilane, trisilane or tetrasilane.

16. The method of claim 14, wherein the deposition plasma further comprises one or more of H₂, Ar or He.

17. The method of claim 11, wherein forming the converted material comprises exposing the surface of the substrate to a directional oxidant plasma and the converted material comprises silicon oxide.

18. The method of claim 17, wherein the directional oxidant plasma comprises a cycle of an O₂/Ar plasma or a N₂O/Ar plasma and an Ar/He plasma.

19. The method of claim 11, wherein selectively etching the sidewall material comprises exposing the substrate to a plasma comprising H₂ or NF₃.

20. (canceled)

21. The method of claim 4, wherein the silicon-containing precursor comprises one or more of silicon tetrafluoride (SiF₄), silicon tetrachloride (SiCl₄), or dichlorosilane (SiH₂Cl₂).

22. The method of claim 1, wherein the silicon film comprises amorphous silicon.

23. The method of claim 1, wherein, subsequent selectively etching the sidewall material over the top material and the bottom material, a thickness of the top material and the bottom material is less than or about 500 A.

24. The method of claim 14, wherein the silicon-containing precursor comprises one or more of silicon tetrafluoride (SiF₄), silicon tetrachloride (SiCl₄), or dichlorosilane (SiH₂Cl₂).

25. The method of claim 11, wherein the silicon film comprises amorphous silicon.
